(19) United States
(12) Patent Application Publication
(10) Pub. No.: US 2017/0135203 A1
(43) Pub. Date: May 11, 2017

(54) Microelectronic Package Using A Substrate With A Multi-Region Core Layer

(71) Applicant: Yuci Shen, Cupertino, CA (US)

(72) Inventor: Yuci Shen, Cupertino, CA (US)

(21) Appl. No.: 14/934,014

(22) Filed: Nov. 5, 2015

(51) Int. Cl. H05K 1/03; H01L 23/498; H05K 1/11; H05K 1/18; H05K 1/02; H01L 23/16; H01L 23/00

(52) U.S. Cl. CPC H05K 1/03; H01L 23/16; H01L 23/49827; H01L 23/49822; H01L 23/562; H05K 1/181; H05K 1/0298; H05K 1/115; H05K 2201/068

(57) ABSTRACT

A microelectronic package comprises at least one substrate and at least one semiconductor die. The substrate includes a multi-region core layer and one or more metal and insulating layers which are stacked on upper and lower sides of the core layer, wherein the core layer includes one or more inner cores with a lower CTE for better matching with the low CTE of semiconductor dies and an outer core with a higher CTE for better matching with the high CTE of PCB on which the package is mounted. Each inner core is positioned at a corresponding die shadow region, and the outer core is positioned outside each die shadow region. The ceramic or glass and organic materials may be respectively selected for the inner and outer cores. The microelectronic package based on the substrate may better meet the reliability requirements on both component and board level.

### TECHNICAL FIELD OF THE INVENTION

The disclosure relates generally to semiconductor die packaging technology, and particularly to an organic substrate with ceramic or glass core for packaging semiconductor dies.

### BACKGROUND OF THE INVENTION

A substrate is a bridge connecting two or more semiconductor dies or electronic devices with a fine pitch of electric contact terminals to another substrate or a PCB (printed circuit board) with a coarse pitch of electric contact terminals. A substrate with a core comprises a core layer, a pattern of through core vias, one or more circuit layers, one or more insulating layers, and one terminal layer on each side of the core layer. The pattern of through core vias are electrically conductive paths that extend completely through the core for connecting the metal layers (circuit layers and terminal layers) on both sides of the core. The core material may include silicon, glass, ceramic or glass fiber reinforced organic material. The manufacture for a substrate with core comprises the basic processing steps: 1) prepare a panel of core (a rectangular piece of organic material, a circular silicon wafer or glass wafer, for example); 2) form a pattern of through core vias in each core unit (a panel of core is usually divided into a plurality of core units for producing a plurality of substrates in a batch); and 3) stack one or more circuit layers, one or more insulating (or dielectric) layers, and one terminal layer on each side of the panel of core so as to form a panel of substrate which is further singulated into a plurality of substrate units, each for a semiconductor die package.

A semiconductor die package or a microelectronic package consisting of a substrate mounted with one or more semiconductor dies may experience two types of reliability issues: one is called the component level reliability issue and the other is called the board level reliability issue. The component level reliability issue includes the excessive warpage of semiconductor die package and stress-related failure inside the package. And the board level reliability issue mainly includes the reliability of solder balls which connect the package to a PCB. The root cause for these reliability issues is the CTE mismatch among silicon dies, substrate and PCB, where silicon dies are mounted on substrate, then mounted on PCB, forming a three layers of structure in the application of the semiconductor die package. The CTE of silicon die and organic PCB are typically about 2.6 ppm and 18 ppm, respectively. And the overall CTE of a substrate is designable, and may range from about 4 ppm to 15 ppm, depending on what core material is used. The component level reliability issue is caused by the CTE mismatch between silicon die and substrate. So, in order to solve the component level reliability issue of a semiconductor die package, the core material with very low CTE is recently preferred, including organic material reinforced with ultra-low CTE glass fibers, ceramic material, and glass material. The substrate with low CTE core material may well reduce the stress-related component level reliability issue. However, it worsens the board level reliability because of the larger CTE mismatch between the package and PCB. Especially, when ceramic or glass material is used for the core of a large substrate, the board level reliability issue become very severe, which limits the application of glass and ceramic as core material of a large substrate.

It is noted that the core of a substrate is a layer of identical material in prior arts. So, it looks like an impossible mission for a substrate to achieve a good CTE match with both a silicon die with a low CTE value of about 2.6 ppm as well as an organic PCB with a high CTE value of about 18 ppm. In the present invention, a substrate with a multi-region core layer consisting of inner and outer cores are described, wherein the inner core(s) have a lower value of CTE for better matching with the low CTE of silicon die(s) at the die shadow or inner region(s) of the substrate, and the outer core has a higher value of CTE for better matching with the high CTE of PCB at the peripheral or outer region of the substrate. As a result, the semiconductor die package based on the substrate of the present invention may better meet the reliability requirements on both component and board levels.

### SUMMARY OF THE INVENTION

A substrate with core layer typically comprises a core layer, a pattern of through core vias, and one or more circuit layers, one or more dielectric layers and one terminal layer on each side of the core layer. It is noted that both circuit layer and terminal layer may be simply called metal layer. The terminal layer is the outmost metal layer on a substrate. The terminal layer on upper side of a substrate is for connecting with one or more semiconductor dies or electronic devices through an array of solder bumps, and the terminal layer on lower side of the substrate is for connecting with a PCB through an array of solder balls. The purpose for using a core layer in an organic substrate is for enhancing the mechanical stiffness and adjusting the overall CTE of the substrate. In prior arts, the core layer is a layer of identical material, typically a polymer material layer with glass fiber reinforced. For further enhancing the stiffness of a substrate, a core layer using ceramic or glass material is also considered. A ceramic or glass core layer should be an ideal selection for achieving a high stiffness of substrate with low CTE. However, there is a big challenge for the adoption of ceramic or glass material as the core layer of an organic substrate, especially for a large substrate with thick core. A ceramic or glass core layer with low CTE dramatically reduces the stress-related component level reliability issue, leading to a low warpage and stress of package in component level. However, due to the low CTE and high modulus of the core layer, the CTE mismatch between the substrate and PCB (where the package using the substrate is mounted on) may cause too high stress in the peripheral or outer solder balls, which are located under the peripheral or outer region of the substrate, leading to a very low board level reliability. Another challenge for the adoption of ceramic or glass material as the core of an organic substrate is the difficulty and high cost of drilling small holes with fine pitch in a thick ceramic or glass core layer, which limits its application in a semiconductor die package that needs fine pitch of through core vias.

The present invention is to solve the two challenges by adopting a low CTE core material such as ceramic or glass material as a core layer of a substrate. Different from the prior arts where the core layer is an identical layer of material, such as ceramic or glass, the core layer of a substrate in the present invention includes multiple regions, i.e., one or more inner cores and one outer core (where more inner cores is for a substrate to package more dies), wherein each inner core is positioned at a corresponding die shadow region. The present innovative idea is based on a realization about how the silicon die, substrate and PCB mechanically interact with each other due to their CTE mismatch when temperature changes. It is realized that the silicon die mainly interacts with the portion of the substrate just underneath the die (or say the portion of the substrate at die shadow region), while the portion of substrate outside the die shadow region interacts with PCB more dominantly. So, the core layer of a substrate including one or more inner cores using lower CTE of material such as ceramic or glass material at each die shadow region, and one outer core using higher CTE of material such as organic material outside each die shadow region of the present invention will reduce the mechanical interaction between silicon die and substrate as well as between substrate and PCB in the meaning time. For a substrate with ceramic or glass as core material, when the core thickness is larger than 0.4 mm, the challenge is to drill small through core vias with fine pitch. The issue is avoided in the present invention by using a core layer with densely dispersed dark through core vias. A core layer with densely dispersed dark through core vias may be efficiently produced by the method disclosed in U.S. Ser. No. 14/821,732. It is noted that the region just underneath the semiconductor die in a package is usually called die shadow region in the semiconductor die packaging community. In the present invention, the term “die shadow region” with the same meaning is used. More specifically, it stands for the region of the core layer just underneath the semiconductor die, and it is preferred that the size of the region is similar as or a little bigger than the corresponding die.

In one preferred embodiment of the present invention, a microelectronic package, comprising: a substrate and one or more semiconductor dies, wherein the one or more semiconductor dies are mounted on the substrate, and the substrate includes a multi-region core layer and one or more metal and insulating layers which are stacked on upper and lower sides of the core layer; the core layer includes one or more inner cores with a lower value of CTE and an outer core with a higher value of CTE, where each inner core is positioned at a corresponding die shadow region, and the outer core is positioned outside each die shadow region. Some more features of the microelectronic package include: 1) the microelectronic package, wherein the multi-region core layer further includes a ring-type transition region between at least one inner core and the outer core, and the material for the ring-type transition region is different from the materials for the inner and outer cores; 2) the microelectronic package, wherein the multi-region core layer further includes a ring-type transition region between at least one inner core and the outer core; the material for the ring-type transition region is different from the materials for the inner and outer cores, and the ring-type transition region between the inner core and the outer core includes a plurality of laminated metal pieces, which are distributed according to a pattern in the transition region, extended through the transition region, and stopped at the upper and lower sides of the transition region; 3) the microelectronic package, wherein a ceramic or glass material and an organic material are separately selected for the inner and outer cores of the multi-region core layer respectively; 4) the microelectronic package, wherein at least one inner core includes a plurality of densely dispersed dark through core vias, which are metal posts that extend through the inner core and stop at the upper and lower sides of the inner core; 5) the microelectronic package, wherein all the inner and outer cores include a plurality of densely dispersed dark through core vias, which are metal posts that extend through the core layer and stop at the upper and lower sides of the core layer.

In another preferred embodiment of the present invention, a substrate, comprising: a core laminate including a multi-region core layer and one or more metal and insulating layers which are stacked on upper and lower sides of the multi-region core layer, wherein the multi-region core layer includes one or more inner cores with a lower value of CTE, and an outer core with a higher value of CTE. Each inner core is positioned at a corresponding die shadow region, and the outer core is positioned outside each die shadow region. Some more features of the substrate include: 1) the substrate, wherein the multi-region core layer further includes a ring-type transition region between at least one inner core and the outer core, and the material for the ring-type transition region is different from the materials for the inner and outer cores; 2) the substrate, wherein the ring-type transition region between the inner core and the outer core includes a plurality of laminated metal pieces, which are distributed according to a pattern in the transition region, extended through the transition region, and stopped at the upper and lower sides of the transition region; 3) the substrate, wherein the multi-region core layer further includes a corner-type transition region between the corners of at least one inner core and the outer core, and the material for the corner-type transition region is different from the materials for the inner and outer cores; 4) the substrate, wherein a ceramic or glass material and an organic material are separately selected for the inner and outer cores respectively; 5) the substrate, wherein at least one inner core includes a plurality of densely dispersed dark through core vias, which are metal posts that pass through the inner core and stop at the upper and lower sides of the inner core; 6) the substrate, wherein the outer core includes a plurality of densely dispersed dark through core vias, which are metal posts that pass through the outer core and stop at the upper and lower sides of the outer core; 7) the substrate, wherein all the inner and outer cores include a plurality of densely dispersed dark through core vias, which are metal posts that pass through the core layer and stop at the upper and lower sides of the core layer; and 8) the substrate, wherein all the inner and outer cores include a plurality of densely dispersed dark through core vias, which are metal posts that pass through the core layer and stop at the upper and lower sides of the core layer; and wherein a metal layer and an insulating layer are stacked on each side of the core layer, each metal layer includes a plurality of metal pads with a desired pattern, the metal pads on the upper side of the core layer align with the metal pads on the lower side of the core layer, forming a plurality of pairs of metal pads, each pair of metal pads are electrically connected by at least one dark through core via, forming an electrically conductive path from the upper to lower side of the core layer at a desired location, and the space between any two neighboring metal pads on the same side of the core layer is bigger than the size of the dark through core via such that one pair of metal pads is electrically insulated from the other pair of metal pads.

In other preferred embodiment of the present invention, a multi-region substrate core layer, comprising: one or more inner cores with a first value of CTE; an outer core with a second value of CTE, wherein the first value of CTE is smaller than the second value of CTE, and at least one inner core includes a plurality of densely dispersed dark through core vias, which are metal posts that pass through the inner core and stop at the upper and lower sides of the inner core. Some further features of the substrate core layer include: 1) the multi-region substrate core layer, wherein the outer core includes a plurality of densely dispersed dark through core vias, which are metal posts that pass through the outer core and stop at the upper and lower portions of the outer core; 2) the multi-region substrate core layer, wherein a ceramic or glass material and an organic material are separately selected as the matrix materials for the inner and outer cores respectively; 3) the multi-region substrate core layer, wherein the core layer further includes a ring-type transition region between at least one inner core and the outer core, and the material for the ring-type transition region is different from the materials for the inner and outer cores; and 4) the substrate core layer, wherein the core layer further includes a ring-type transition region between at least one inner core and the outer core, wherein the material for the ring-type transition region is different from the materials for the inner and outer cores, and the ring-type transition region between the inner core and the outer core includes a plurality of laminated metal pieces which are distributed according to a pattern in the transition region, extended through the transition region, and stopped at the upper and lower sides of the transition region.

An illustrative example of a semiconductor die package using a substrate with a multi-region core layer including one inner core and an outer core according to the present invention is schematically showed in FIG. 2 and FIG. 4A. A specific example of a substrate with a multi-region core layer including one inner core and an outer core according to the present invention is described as: the material for the inner core is low temperature co-fired ceramic (LTCC) with a lower value of CTE from about 4 ppm to 8 ppm, the thickness of the inner core is about 0.15 mm to 0.8 mm, and the inner core includes densely dispersed dark through core vias with via diameter of about 10 um to 30 um and via pitch of about 20 um to 40 um; the material for the outer core is an organic material with a higher value of CTE from about 14 ppm to 18 ppm, the thickness of the outer core is the same as the inner core thickness, and the outer core includes densely dispersed dark through core vias with via diameter of about 10 um to 30 um and via pitch of about 20 um to 40 um, the location of the inner core is positioned at the die shadow region, and the size of the inner core is a little bigger than the die size (for example, if the die size is 25 mm×25 mm, the size of the inner core may be about 26 mm×26 mm).

One advantage of the present invention is that the microelectronic package based on the substrate with inner and outer cores may better meet the reliability requirements on both component and board levels. The second advantage the present invention is that a ceramic or glass inner core with large size and thickness may be used due to the adoption of core material with dark through core vias. More advantages of the present invention include a substrate with multiple inner cores that may be designed for packaging multiple dies or electronic devices.

One key idea in the present invention is to introduce a substrate with one or more inner cores with a lower value of CTE at each corresponding die shadow region and an outer core with a higher value of CTE outside each die shadow region. Another key idea in the present invention is to use a core layer with dark through core vias such that a substrate with thick ceramic or glass core becomes feasible in the application where fine pitch of electrically conductive paths through core layer are needed. More features, advantages, and inventive concepts of the present invention are described with reference to the detailed description of the embodiments of the present invention below.

### BRIEF DESCRIPTION OF THE DRAWINGS

FIG. 1 is a schematic diagram for illustrating a typical semiconductor die package, where a semiconductor die (or chip) is connected with a substrate electrically and mechanically through solder bumps and underfill material of prior arts.

FIG. 1A is a schematic diagram for illustrating the core layer of a substrate of prior arts.

FIG. 1B is a schematic diagram for illustrating a semiconductor die package mounted on a PCB, forming a three layers of structure of prior arts.

FIG. 2 is a schematic diagram for illustrating a semiconductor die package, wherein the core layer of the substrate includes an inner core with lower CTE and an outer core with higher CTE, and the inner core is positioned at the die shadow region of one embodiment of the present invention.

FIG. 2A is a schematic diagram for illustrating a multi-region core layer of a substrate wherein the core layer includes an inner core with lower CTE and an outer core with higher CTE, and the inner core is positioned at the die shadow region of one embodiment of the present invention.

FIG. 2B is a schematic diagram for illustrating a semiconductor die package mounted on a PCB, forming a three layers of structure of one embodiment of the present invention.

FIG. 3 is a schematic diagram for illustrating a multi-region core layer of a substrate, where the core layer includes multiple inner cores (4 inner cores in this example) and an outer core for a multiple die package of one embodiment of the present invention.

FIG. 4 is a schematic diagram for illustrating a multi-region core layer of a substrate wherein the inner core of the core layer includes a plurality of densely dispersed dark through core vias, which are metal posts that extend through the inner core and stop at the upper and lower sides of the inner core of one embodiment of the present invention.

FIG. 4A is a schematic diagram for illustrating a semiconductor die package, wherein the multi-region core layer of the substrate includes an inner core consisting of a lower CTE of matrix material with densely dispersed dark through core vias of one embodiment of the present invention.

FIG. 4B is a schematic diagram for illustrating a metal layer and then an insulating layer are stacked on each side of a multi-region core layer with densely dispersed dark through core vias, forming a plurality of electrically conductive paths from the upper to lower sides of the core layer of one embodiment of the present invention.

FIG. 4C is a schematic diagram for illustrating an insulating layer and then a metal layer are stacked on each side of a multi-region core layer with densely dispersed dark through core vias, forming a plurality of electrically conductive paths from the upper to lower sides of the core layer of one embodiment of the present invention.

FIG. 5 is a schematic diagram for illustrating a multi-region core layer having a ring-type transition region between the inner core and the outer core of one embodiment of the present invention.

FIG. 5A is a schematic diagram for illustrating a multi-region core layer having a corner-type transition region between the corners of the inner core and the outer core of one embodiment of the present invention.

FIG. 5B is a schematic diagram for illustrating a multi-region core layer with a ring-type of transition region between its inner and outer cores, wherein a plurality of laminated metal pieces are distributed according to a pattern in the ring-type of transition region, extended through the transition region, and stopped at the upper and lower sides of the transition region of one embodiment of the present invention.

### DETAILED DESCRIPTION OF THE PREFERRED EMBODIMENTS

The terms used in the detailed description are explained herein for illustrative clarity: 1) die shadow region means the region just underneath the semiconductor die in a semiconductor package, more specifically, it stands for the region of the substrate core layer just underneath the die, and the size of the region is similar as or a little bigger than the corresponding die; and 2) a dark through core via means a through core via with its location not defined or unknown, the through core via may be a metal post that extend through the core layer and stop at the upper and lower sides of the core layer. These terms are further explained by referring to the drawings when describing the preferred embodiments of the present invention.

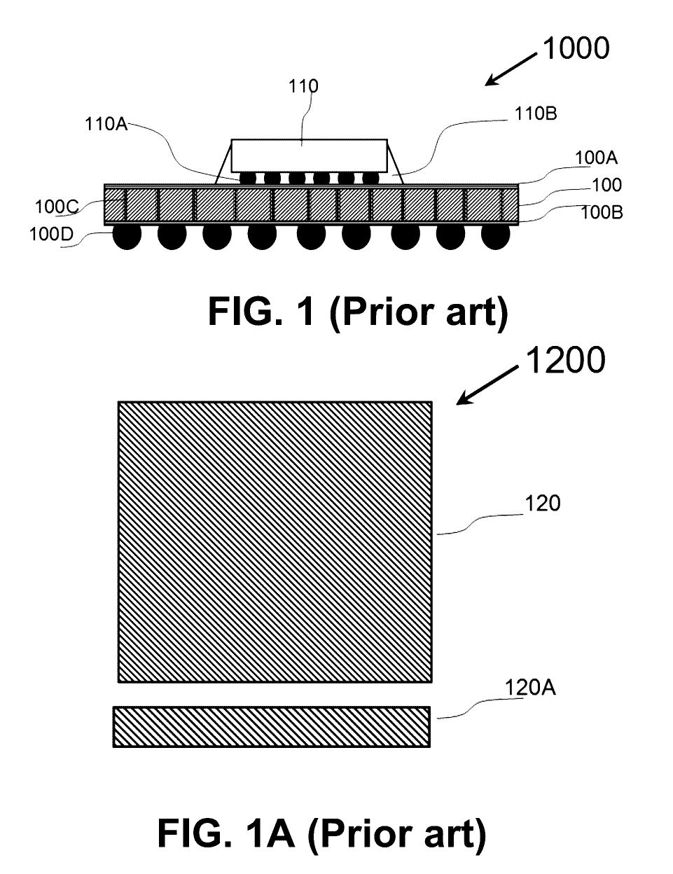

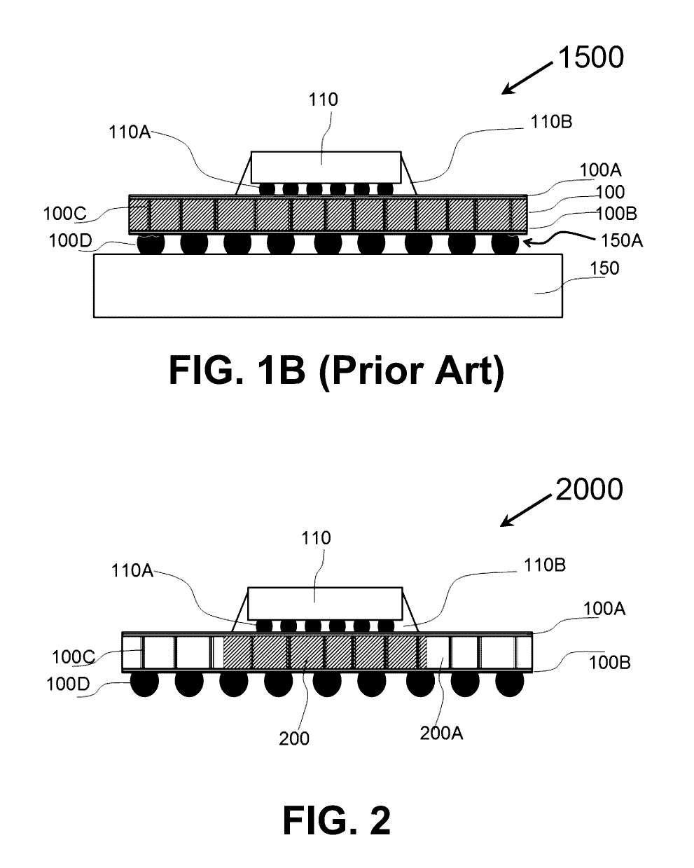

FIG. 1-1B are schematic diagrams for illustrating a semiconductor die package, the core layer in the substrate, and a three layers of structure when the package is mounted on a PCB of prior arts. FIG. 1 illustrates a semiconductor die package 1000, where the numerical symbol 110 designates a semiconductor die, 100, 100A, 100B and 100C respectively designate the core layer, upper metal and insulating layers, lower metal and insulating layers, and through core vias of a substrate, 110A and 110B designate solder bumps and underfill material for connecting the die 110 with the substrate electrically and mechanically, and 100D designates an array of solder balls which will connect the package to a PCB. FIG. 1A illustrates a substrate core layer of prior arts, where the numerical symbol 120 and 120A respectively designate its top and side view. FIG. 1B illustrates a three layers of structure 1500, where the die 110 is mounted on the substrate (100, 100A, 100B, 100C) through solder bumps 110A and underfill material 110B, then mounted on the PCB 150 through solder balls 100D, and the numerical symbol 150A illustrates a possible failure risk of peripheral solder balls when a low CTE of core material such as ceramic or glass material is adopted. The semiconductor die package 1000 is called a flip chip BGA package. The component level reliability issue (including its warpage and stress-related failures such as solder bump cracking, dielectric layer cracking inside the silicon die, underfill corner cracking and others) must be considered when it is designed. Because the component level reliability issue is caused by the CTE mismatch between the die and the substrate, some very low CTE of core material is adopted, including ultra-low CTE of glass fiber reinforced polymer core, ceramic core and glass core. As a result, the component level reliability issue is well reduced. However, when the package is mounted on a PCB as illustrated in FIG. 1B, the CTE mismatch between the substrate and the PCB will become much more severe, causing the higher failure risk as showed by the numerical symbol 150A in the peripheral solder balls. It looks like an impossible mission for a substrate with an identical material of core layer 1200 to get good CTE match with both silicon die 110 with a low CTE value of about 2.6 ppm and a PCB 150 with a high CTE value of about 18 ppm.

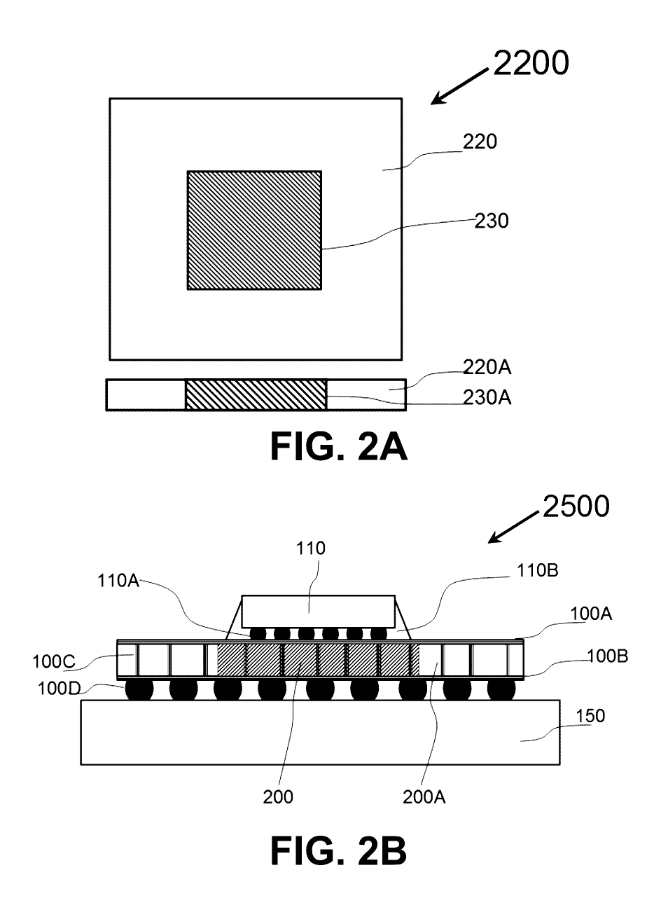

It is realized in the present invention that the silicon die 110 mainly interacts with the portion of the substrate just underneath the die (or say the portion of the substrate at die shadow region), causing the component level reliability issue, while the portion of substrate outside the die shadow region interacts with PCB more dominantly, causing the board level reliability issue. So, a core layer of a substrate including one or more inner cores using a lower CTE of material such as ceramic or glass material at each die shadow region, and an outer core using a higher CTE of material such as organic material outside each die shadow region will well reduce the mechanical interaction between the silicon die 110 and substrate as well as between the substrate and PCB 150. As a result, a semiconductor die package 2000 as illustrated in FIG. 2 is described according to one preferred embodiment of the present invention, where the same numerical symbols designate the same items as those in the preceding and following figures, and numerical symbols 200 and 200A designate a multi-region core layer, which includes an inner core 200 and an outer core 200A, wherein the inner core 200 with a little bigger size than the size of the silicon die 110 is preferred, and the outer core 200A is positioned outside the die shadow region or at the peripheral of the core layer. FIG. 2A illustrates a multi-region substrate core layer 2200 consisting of an inner core 230 and an outer core 220 of one preferred embodiment of the present invention, where the numerical symbol 220 or 220A designate the top and side view of the outer core, and the numerical symbol 230 or 230A designate the top and side view of the inner core. FIG. 2B illustrates a three layers of structure 2500, where the package 2000 illustrated in FIG. 2 is mounted on the PCB 150. It is clear that the stress of the peripheral solder balls between the outer core 200A and the PCB will be low because the high CTE of the outer core 200A well matches with the high CTE of the PCB, while the stress of the solder bumps 110A, underfill material 110B and others inside the package will be also low because the low CTE of the inner core 200 well matches with the low CTE of the silicon die 110.

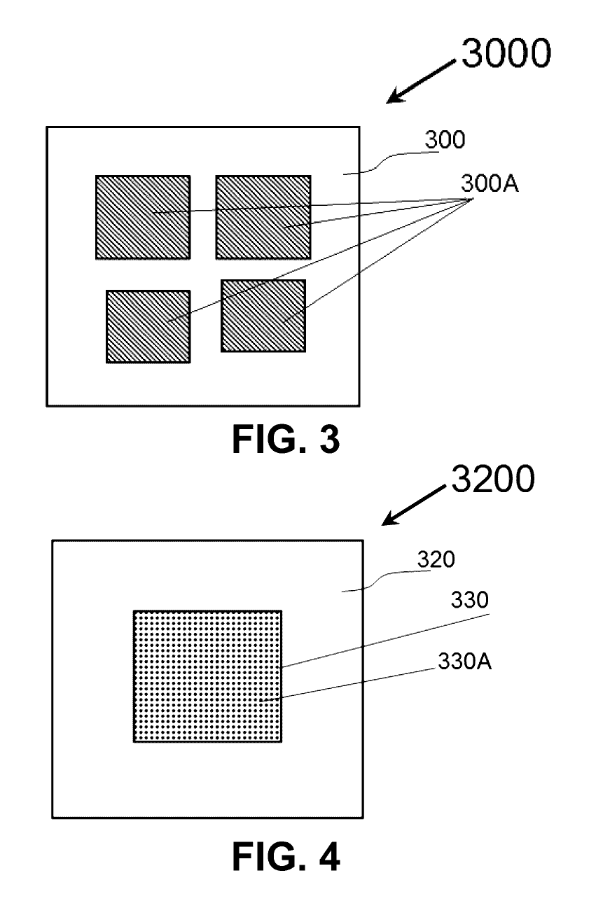

One semiconductor die mounted on the substrate is only illustrated in the package in the preceding FIG. 2-2B. As a semiconductor die package with higher performance and lower power consumption continues to be desired, more semiconductor dies need to be mounted on a common substrate, forming the so-called SiP (system in package) type or MCM type (multiple chip modules) of package. The present concept of a semiconductor die package based on a substrate with inner and outer cores can be similarly extended for the case of multiple dies. FIG. 3 is a schematic diagram for illustrating a multi-region substrate core layer 3000 which consists of four inner cores 300A and an outer core 300. The sizes and locations of the four inner cores is defined according to the four dies which is desired to be packaged in the substrate with the core layer, wherein each inner core is positioned at each corresponding die shadow region and the size of each inner core is preferred to be a little bigger than the size of the corresponding die.

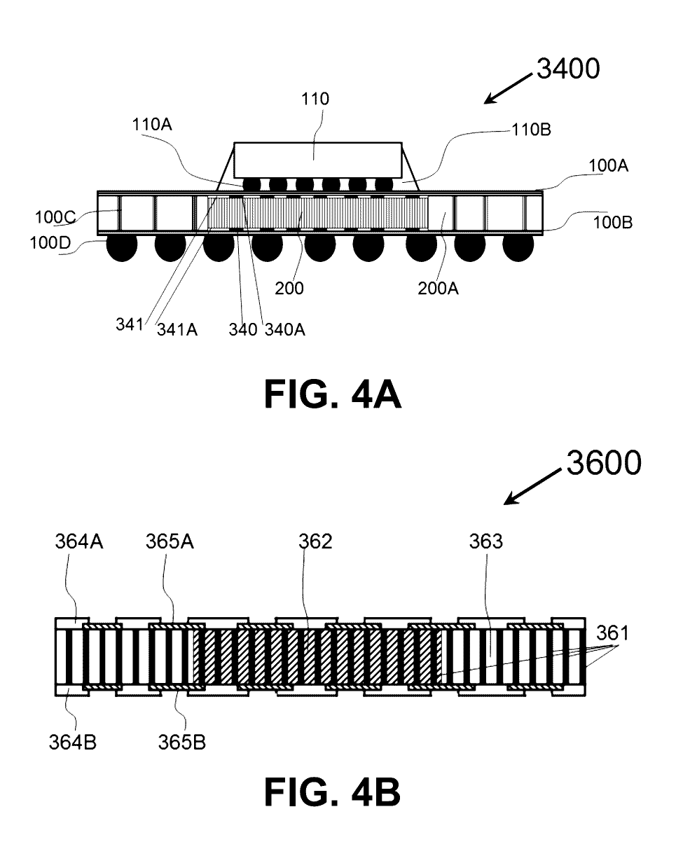

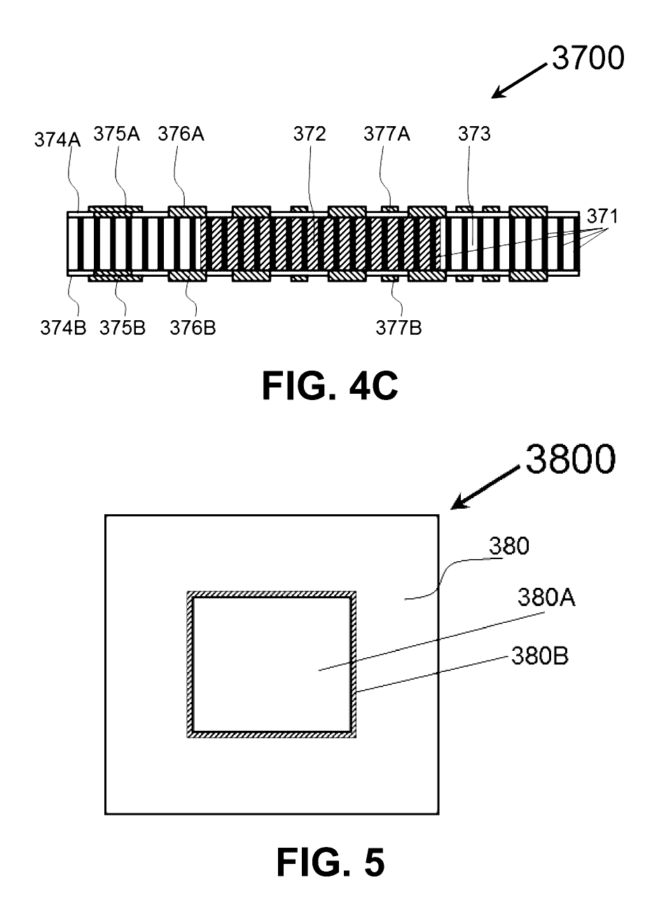

The multi-region substrate core layer of the present invention may have some further features. FIG. 4 is a schematic diagram for illustrating a substrate core layer 3200, wherein the inner core 330 includes a plurality of densely dispersed dark through core vias 330A, which are metal posts that extend through the inner core and stop at the upper and lower sides of the inner core 330. It is noted that the outer core 320 may also include a plurality of densely dispersed dark through core vias, which are not plotted in the figure for simplicity and clarity. It is noted that the locations of the plurality of densely dispersed dark through core vias 330A do not have to be defined. A substrate core layer with densely dispersed dark through core vias may be efficiently produced through slicing a composite column consisting of a matrix material filled with densely dispersed metal wires, referring to the U.S. Ser. No. 14/821,732 of the inventor.

FIG. 4A is a schematic diagram for illustrating a semiconductor die package 3400, wherein the multi-region core layer of the substrate includes an inner core 200 consisting of a lower CTE of matrix material with densely dispersed dark through core vias of one embodiment of the present invention, and wherein the desired electrically conductive paths from the upper to lower sides may be achieved through a plurality of pairs of metal pads designated by the numerical symbols 340 and 340A. A pair of metal pads such as that designated by 340 and 340A may be produced at a desired location. A pair of metal pads electrically connected by at least one dark through core vias forms a desired electrically conductive path from the upper to lower sides of the core layer. And the other dark through core vias outside metal pads are covered by insulating material layer as designated by 341 and 341A so that they are electrically dummy.

FIG. 4B and FIG. 4C are schematic diagrams for more clearly illustrating how the desired electrically conductive paths may be formed through a pair of metal layers based on a substrate core layer with densely dispersed dark through core vias of one embodiment of the present invention. Referring to FIG. 4B, the inner and outer core include a plurality of densely dispersed dark through core vias 361. The numerical symbols 362 and 363 respectively designate the matrix materials for the inner core and outer core. An upper metal layer including a plurality of metal pads 365A and a lower metal layer including a plurality of metal pads 365B are first stacked on the both sides of the core layer, and then an upper insulating layer 364A and a lower insulating layer 364B are stacked on the both sides of the core layer and over the metal layers, wherein the upper metal pads align with the lower metal pads, forming a plurality of pairs of metal pads. Each pair of metal pads such as 365A and 365B forms an electrically conductive path from the upper to lower side of the core layer, where at least one dark through core via connects the pair of metal pads because the dark through core vias are much denser than the metal pads. Referring to FIG. 4C, the inner and outer core include a plurality of densely dispersed dark through core vias 371. The numerical symbols 372 and 373 respectively designate the matrix materials for the inner core and outer core. An upper insulating layer 374A and a lower insulating layer 374B are first stacked on the both sides of the core layer, then a pattern of openings is formed in both insulating layers, and then an upper metal layer including a plurality of metal pads 375A or 376A and a lower metal layer including a plurality of metal pads 375B or 376B are formed inside the openings of the two insulating layers, the upper metal pads align with the lower metal pads, forming a plurality of pairs of metal pads; each pair of metal pads such as 375A and 375B forms an electrically conductive path from the upper to lower sides of the core layer. It is noted that the structure of metal and insulating layers with metal layer stacked first illustrated in FIG. 4B in fact electrically transfers the metal pads from the upper to lower sides of the core layer, while the structure of metal and insulating layers with insulating layers stacked first illustrated in FIG. 4C may produce more metal elements on both side of the core layer such as metal traces 377A or 377B.

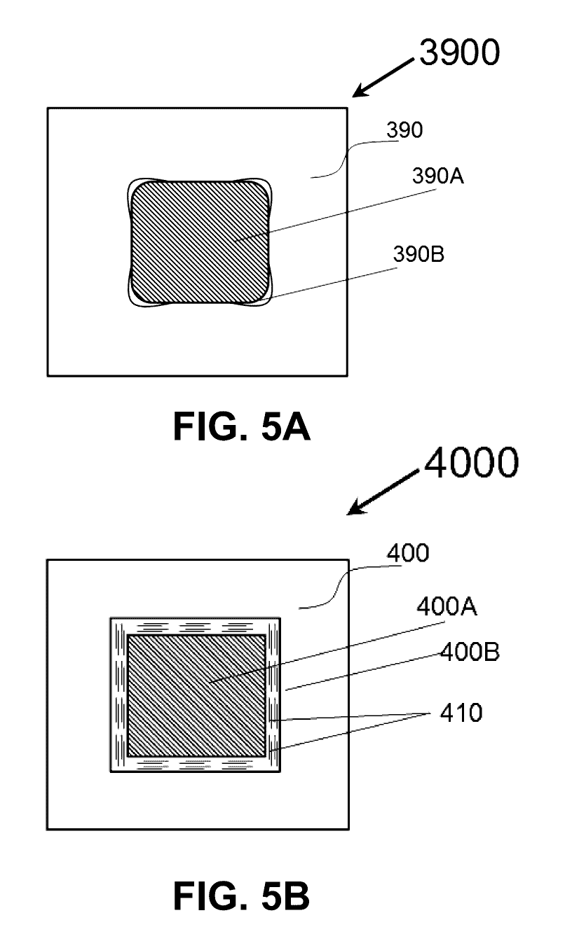

FIG. 5-5B are schematic diagrams for illustrating some more features of the multi-region substrate core layer of one embodiment of the present invention. Referring to FIG. 5, a substrate core layer 3800 with an inner core 380A and an outer core 380, wherein the core layer further includes a ring-type transition region 380B between the inner core 380A and the outer core 380, and the material for the ring-type of transition region 380B is different from the materials for the inner core 380A and outer core 380. Referring to FIG. 5A, a substrate core layer 3900 with an inner core 390A and an outer core 390, the core layer further includes a corner-type transition region 390B between the corners of the inner core and the outer core, and the material for the corner-type transition region is different from the materials for the inner 390A and outer cores 390. The purpose using the ring-type transition region 380B or the corner-type transition region 390B is to enhance the bonding strength and mechanical reliability between the inner and outer cores. Another purpose to use a ring-type of transition region is that some metal or electronic elements may be added in it. For example, FIG. 5B is for illustrating a core layer of a substrate, wherein the ring-type transition region between the inner core 400A and the outer core 400 includes a plurality of laminated through core metal pieces 410, which are distributed according to a pattern in the transition region, extended through the transition region, and stopped at the upper and lower sides of the transition region. These laminated through core metal pieces 410 may further form passive electric components such as capacitors in the example by combining with the metal structure in upper and lower circuit layers.

It is noted that one key idea in the present invention is to introduce a multi-region substrate core layer in a substrate or a semiconductor die package. As a result, when a lower CTE of material and a higher CTE of material are respectively selected for the inner core(s) and the outer core, the semiconductor die package based on the substrate of the present invention may better meet the reliability requirements in both component and board levels in the meantime. Another key idea in the present invention is to use a core layer with dark through core vias such that a substrate with fine pitch of electrically conductive paths through thick ceramic or glass core layer may be efficiently produced according to the need in an application.

Although the present invention is described in some details for illustrative purpose with reference to the embodiments and drawings, it is apparent that many other modifications and variations may be made without departing from the spirit and scope of the present invention.

What is claimed is:

1. A microelectronic package, comprising:
a substrate and one or more semiconductor dies, wherein the one or more semiconductor dies are mounted on the substrate, the substrate includes a multi-region core layer and one or more metal and insulating layers which are stacked on the upper and lower sides of the multi-region core layer, the multi-region core layer includes one or more inner cores with a lower value of CTE and one outer core with a higher value of CTE, each inner core is positioned at a corresponding die shadow region, and the outer core is positioned outside of the die shadow regions.

2. The microelectronic package of claim 1, wherein a ceramic or glass material and an organic material are respectively selected for the inner and outer cores.

3. The microelectronic package of claim 1, wherein at least one inner core includes a plurality of densely dispersed dark through core vias, which are metal posts that extend through the inner core and stop at the upper and lower sides of the inner core.

4. The microelectronic package of claim 1, wherein all the inner and outer cores include a plurality of densely dispersed dark through core vias, which are metal posts that extend through the core layer and stop at the upper and lower sides of the core layer.

5. The microelectronic package of claim 1, wherein the core layer further includes a ring-type transition region between at least one inner core and the outer core, and the material for the ring-type transition region is different from the materials for the inner and outer cores.

6. The microelectronic package of claim 5, wherein the ring-type transition region between the inner core and the outer core includes a plurality of laminated metal pieces, which are distributed according to a pattern in the transition region, extended through the transition region, and stopped at the upper and lower sides of the transition region.

7. A substrate, comprising:
a core laminate including a multi-region core layer and one or more metal and insulating layers which are stacked on upper and lower sides of the core layer, wherein the multi-region core layer includes one or more inner cores with a lower value of CTE and an outer core with a higher value of CTE, each inner core is positioned at a corresponding die shadow region, and the outer core is positioned outside the die shadow regions.

8. The substrate of claim 7, wherein the multi-region core layer further includes a ring-type transition region between at least one inner core and the outer core, and the material for the ring-type of transition region is different from the materials for the inner and outer cores.

9. The substrate of claim 8, wherein the ring-type of transition region between the inner core and the outer core includes a plurality of laminated metal pieces, which are distributed according to a pattern in the transition region, extended through the transition region, and stopped at the upper and lower sides of the transition region.

10. The substrate of claim 7, wherein the multi-region core layer further includes a corner-type transition region between the corners of at least one inner core and the outer core, and the material for the corner-type transition region is different from the materials for the inner and outer cores.

11. The substrate of claim 7, wherein a ceramic or glass material and an organic material are respectively selected for the inner and outer cores.

12. The substrate of claim 7, wherein at least one inner core includes a plurality of densely dispersed dark through core vias, which are metal posts that extend through the inner core and stop at the upper and lower sides of the inner core.

13. The substrate of claim 7, wherein the outer core includes a plurality of densely dispersed dark through core vias, which are metal posts that extend through the outer core and stop at the upper and lower sides of the outer core.

14. The substrate of claim 7, wherein all the inner and outer cores include a plurality of densely dispersed dark through core vias, which are metal posts that extend through the core layer and stop at the upper and lower sides of the core layer.

15. The substrate of claim 14, wherein a metal layer and an insulating layer are stacked on each side of the multi-region core layer; each metal layer includes a plurality of metal pads with a desired pattern, the metal pads on the upper side of the core layer align with the metal pads on the lower side of the core layer, forming a plurality of pairs of metal pads; each pair of metal pads are electrically connected by at least one dark through core via, forming an electrically conductive path from the upper to lower sides of the core layer at a desired location, and the space between any two neighboring metal pads on the same side of the core layer is bigger than the size of the dark through core via such that one pair of metal pads is electrically insulated from the other pairs of metal pads.

16. A multi-region substrate core layer, comprising:
one or more inner cores with a first value of CTE;
an outer core with a second value of CTE;
wherein the first value of CTE is smaller than the second value of CTE, and at least one inner core includes a plurality of densely dispersed dark through core vias, which are metal posts that extend through the inner core and stop at the upper and lower sides of the inner core.

17. The multi-region substrate core layer of claim 16, wherein the outer core includes a plurality of densely dispersed dark through core vias, which are metal posts that extend through the outer core and stop at the upper and lower sides of the outer core.

18. The multi-region substrate core layer of claim 16, wherein a ceramic or glass material and an organic material are respectively selected as the matrix materials for the inner and outer cores.

19. The multi-region substrate core layer of claim 16, wherein the core layer further includes a ring-type of transition region between at least one inner core and the outer core, and the material for the ring-type transition region is different from the materials for the inner and outer cores.

20. The multi-region substrate core layer of claim 19, wherein the ring-type of transition region between the inner core and the outer core includes a plurality of laminated metal pieces, which are distributed according to a pattern in the transition region, extended through the transition region, and stopped at the upper and lower sides of the transition region.
